(19) United States
(12) Patent Application Publication
(10) Pub. No.: US 2025/0260405 A1
(43) Pub. Date: Aug. 14, 2025

(54) PROGRAMMABLE GATE ARRAY AND METHOD OF GENERATING CONFIGURATION DATA FOR PROGRAMMING A GATE ARRAY

(71) Applicant: dSPACE GmbH, Paderborn (DE)

(72) Inventors: Heiko KALTE, Paderborn (DE); Dominik LUBELEY, Verl (DE)

(73) Assignee: dSPACE GmbH, Paderborn (DE)

(21) Appl. No.: 19/051,914

(22) Filed: Feb. 12, 2025

(30) Foreign Application Priority Data
Feb. 12, 2024 (EP) 24157108

(51) Int. Cl. H03K 19/173; G01R 31/317; G01R 31/319; G06F 9/30

(52) U.S. Cl. CPC H03K 19/1737; G01R 31/31724; G01R 31/319; G06F 9/30116

(57) ABSTRACT

A programmable gate array that is set up to perform a function and to use at least one signal by at least one function part of the function when performing the function. The gate array has at least one detection element which is set up to determine, using a change to the signal, whether the at least one function part is run on the gate array when the function is performed, and to provide at least one detection value dependent on the determination. A computer arrangement is also provided, which has such a gate array, a use of such a computer arrangement, a test device which has such a computer arrangement, and a method for generating configuration data for programming such a gate array.

This nonprovisional application claims priority under 35 U.S.C. § 119(a) to European Patent Application No. 24157108.2, which was filed on Feb. 12, 2024, and which is herein incorporated by reference.

### BACKGROUND OF THE INVENTION

### Field of the Invention

The application relates to a programmable gate array, a computer assembly having the gate array, a use of the computer assembly and a test device for testing a control unit. The application also relates to a method for generating configuration data for the purpose of programming a gate array.

### Description of the Background Art

Devices for performing control and/or regulation tasks in vehicles are also referred to as control units. Control units in vehicles, especially motor vehicles, may have a computing unit, memory, interfaces, and possibly other components that are necessary for the processing of input signals with data input into the control unit and the generation of control signals with output data. The interfaces are used to receive the input signals or to output the control signals.

In a test device, it is possible to test the development status of the control unit or its software in an emulated environment. Such test environments can also have hardware-in-the-loop simulators (HILs). The hardware-in-the-loop simulators can be used to emulate a working environment of the control unit (ECU, electronic control unit). The test environment is used to develop and test ECUs in a largely virtual environment without risk and under reproducible conditions.

The test environment may have command-based processors and/or programmable gate arrays. A programmable gate array is generally characterized by a large number of logic units, each comprising one or more logic gates, whose functionality and interconnection can be changed by programming. The programmable gate array, in particular a Field Programmable Gate Array (FPGA), can have other resources in addition to the logic units that, like the logic units, can be connected and integrated into the program logic, such as RAM blocks, registers or integrated signal processors.

An advantage of programmable gate arrays is their ability to operate on a single computing unit to perform many computing or logic operations in parallel. FPGAS are examples of powerful programmable gate arrays. Other examples are CPLDs (Complex Programmable Logic Devices) and PALs (Programmable Array Logics).

DE102020116872A1, which corresponds to US 2021/0303501, which is incorporated herein by reference, describes a method for programming a programmable gate array in a distributed computer system.

### SUMMARY OF THE INVENTION

It is therefore an object of the invention to provide a programmable gate array that is set up to perform a function and to use at least one signal by at least one function part of the function when executing the function. The gate array can have at least one detection element that is set up to determine, using a change to the signal, whether the at least one function part is being run on the gate array when the function is performed. The detection element can be further set up to provide at least one detection value dependent on the determination.

Such a gate array makes it possible to analyze the execution of the function of the programmable gate array. In particular, coverage of the function during execution can be determined and analyzed. The coverage relates to the run, i.e., at least partially run, function parts of the function.

A computer arrangement, according to an example of the invention, can have the aforementioned gate array as well as a processor unit. The processor unit is set up to evaluate at least one detection value to at least one result value.

It is proposed to use the computer arrangement to test an ECU or to simulate an ECU.

A test device for testing a control unit can have the aforementioned computer arrangement. In this case, the gate array can be used to test the control unit by means of a data exchange with the control unit and/or the control unit can be simulated by means of the gate array.

In a method for generating configuration data for programming a gate array from a model, the model specifies a function to be performed by the gate array. When the function is performed on the gate array, at least one signal is used by at least one function part of the function. The method can comprise: receiving input data for the model; automated placement of at least one detection element in the model, wherein the at least one detection element is set up to determine whether the at least one function part of the function is being performed by means of a change to the signal when the function is performed on the gate array and to provide at least one detection value dependent on the detection; and generating the configuration data for programming the gate array from the model.

The described gate array, its use and the described method make it possible to analyze the performance of function parts during the execution of the function on the gate array. For example, it makes it possible to determine whether or not certain function parts of the function were run on the gate array when the function was performed. This makes it possible to determine the so-called coverage for such a gate array. For example, when testing the gate array, the coverage can specify as a so-called test coverage, whether or not, for example, a respective function part of the function of the gate array was actually carried out in the test. This can then be saved, e.g., for documentation purposes, to prove that the respective function has also been tested in a test. However, it can also be used to run the function parts in a further test that have not yet been run in a first test.

Such an analysis of the gate array is made possible by the described gate array, its use, and the described method in real time, since the at least one detection element is provided on the gate array and can provide the at least one detection value when executing the function in real time. The coverage can therefore be detected at runtime. This is much faster than using simulation-based methods for coverage analysis that do not run on the gate array. A corresponding acceleration results for the computer arrangement. The same applies to the test device for testing the control unit that has this computer arrangement.

The method for generating configuration data for programming such a gate array from a model allows for the creation of such a gate array, which enables the above analysis to determine which function parts of the function performed by the gate array were run. The model defines the function that can be performed by the gate array. In particular, the method enables the automatic placement of the at least one detection element in the model. The placement can be visualized, for example, on a graphical user interface. Automatic placement can be started by a user entry. The user can make a choice, for example, via selection menus, which then automatically leads to the placement of the at least one detection element.

Examples of programmable gate arrays can be found in DE102020116872A1, which, as noted above, corresponds to US 2021/0303501, and which are both incorporated herein by reference. Such programmable gate arrays can also be used, for example, for this application.

Depending on the task of the gate array, a function is an action that simulates, for example, a battery current or the output signal of a current sensor or even a control signal. When this function is performed, at least one signal is used by at least one function part of the function. This means that the signal is used in at least part of the function. Optionally, more than one function can be implemented in a gate array. For example, the gate array can include an electric motor and/or power electronics that control and drive the electric motor, and/or a battery. Alternatively, it is possible for the gate array to simulate a control unit that controls the battery and/or the power electronics. Accordingly, the necessary functions are then implemented in the gate array.

Furthermore, a detection element is provided which is set up to determine, using a change to the signal, whether the at least one function part is being run on the gate array when performing the at least one function. Depending on this, the detection value is made available. The detection value thus makes it transparent whether a respective function part was actually run when the function was performed. This makes the so-called coverage of the function comprehensible. The detection value can be a logical, e.g., binary value, or a number, e.g., natural number, or a continuous value. The detection element includes an interface that allows for the detection value to be tapped. The detection element has electrical components for this purpose, which make it possible to determine a change to the signal and thus whether the function part is being run. This is then provided in the detection value, which is dependent on the signal change.

In a further step, the detection value can be evaluated to create a result value. This can be done, for example, in the gate array itself. Alternatively or additionally, the evaluation can also be provided in a processor unit.

The computer arrangement has the programmable gate array described above and the processor unit. The processor unit is provided to evaluate the at least one detection value to the at least one result value. It is also optionally possible for the gate array to take over this task of evaluating the at least one detection value for the at least one result value itself. The result value can contain a statistical evaluation of several detection values or values derived from them. Furthermore, it is possible that by means of the detection value and/or by means of the result value, counter values are stored over the runtime of the performance of the function in order to obtain the total number of changes to the signal. The evaluation of the at least one result value can also include a mean or median calculation. It is also possible to capture maximum and/or minimum values.

For example, the control unit is understood to be a control unit in a vehicle for controlling an electric drive, so that the control unit controls an electric motor, the power electronics, and/or a traction battery. A control unit receives at least one input signal via an input interface and analyzes this and, as a function of this analysis, generates at least one control signal that is output via an output interface. The input signal can be a sensor signal that represents, e.g., accelerator pedal operation. Output signals from other control units can also be such input signals.

On the one hand, the computer arrangement can be used to test the ECU and, for example, emulate the working environment of the ECU. The computer arrangement can supply signals from the ECU environment to the ECU, and record and process corresponding signals from the ECU. Alternatively, the computer arrangement itself can simulate such a control unit, e.g., the development status of the control unit or a version of the software, and can be connected to a battery or an electric motor or power electronics or a combination thereof, for example, in order to check whether the periphery of the control unit works with the simulated control unit and/or to check the development status of the control unit.

The computer arrangement may therefore be located in a test device for testing this ECU. Such test devices are used, for example, by vehicle manufacturers and suppliers to test the ECUs or their peripherals. There is a data exchange with the control unit, which has the corresponding interfaces for it. This data exchange can take place, for example, via a data bus or direct data lines. It is also possible to exchange data via lines, which are also used to exchange energy, for example.

The programmable gate array is programmed from configuration data, wherein the configuration data is derived from a model. The model specifies the function to be performed by the gate array. The model can also be referred to as a system description. Input data, either entered by a user via a graphical user interface or loaded from a memory, is used to create the model, which defines the function.

The detection elements are then placed automatically, in the model, so that the detection elements can then be used to check whether or not function parts were used in the execution of the function, for example during testing. The configuration data can be generated from the model in order to program and thus implement the gate array. The configuration data can also be referred to as a bit stream.

It is provided to program the gate array via an input of a model, wherein the model, as a kind of system description, specifies the function that can be performed by the gate array. The detection element is programmable via the model on the gate array. The location of the detection element and, if applicable, the locations of several detection elements in the model and thus on the gate array can be automatically defined, for example, according to a predefined algorithm.

In addition, it is provided that the gate array has a readout logic that is designed to output the at least one detection value provided by the detection element. The readout logic can, for example, read the detection value from a memory of the detection element and pass it on.

The readout logic can be set up to output the at least one detection value during the execution of the function or after the execution of the function has ended. This ensures that even during the execution of the function, e.g., during the execution of the test, the detection value, for example, is available, so that it can be monitored which functions or function parts have already been run. Alternatively, the detection value can be output at the end of the execution of the function, so that the monitoring of the execution of the function is then documented. This last embodiment requires larger meters and/or larger memories in the detection element.

Also, the readout logic can be set up to output the at least one detection value via a multiplexer unit via a bus or to output it via a shift register chain via a bus. This means that the readout logic has a multiplexer unit that makes it possible to pass the detection value to a bus, or the transmission is implemented via a shift register chain. A multiplexer is a device that selects between different input signals and then switches the selected input signal to an output interface, e.g., an interface to a bus.

The readout logic can be set up to output the at least one detection value via a configuration interface via a bus, wherein the configuration interface is set up to receive the configuration data for programming the gate array. This means that such a configuration interface can generate an additional benefit by using it to output the detection value. The configuration interface in this embodiment thus has the readout logic or vice versa. It is also possible that the configuration interface corresponds to the readout logic. In addition to receiving the configuration data, the readout logic of the configuration interface can also be designed to read the configuration data from the gate array. The configuration data read out can in particular have the at least one detection value. In such an embodiment, the reading of the configuration data thus includes the reading of the at least one detection value.

The detection element can contain at least one shadow register to receive the at least one detection value. The detection element can thus make the at least one detection value available to be read in the at least one shadow register. The at least one shadow register has a memory area for this purpose, from which the at least one detection value can be read via the configuration interface independently of the function performed. The at least one shadow register stores the at least one detection value since the shadow register does not provide for overwriting when the function is performed. Therefore, the detection value can then be read from this at least one shadow register independently of the function being performed.

The at least one detection element can include a counter that can be used to record a number of changes to the at least one signal, wherein the at least one detection element is set up to determine, using the number of changes to the at least one signal, how often the at least one function part is run when the function is performed on the gate array, and to display the result as the at least one detection value. Such a detection element can be used to further improve the analysis of the coverage, as it is not only possible to detect whether a function part has been run, but also how often.

In addition, it is provided that the detection element can be set up to transmit predefined bits of the at least one detection value to the at least one shadow register. This can reduce the storage requirement for the shadow register.

The at least one shadow register can be set up for a logarithmic storage of the at least one detection value. This is particularly advantageous when storing numbers, e.g., the number of executions of a function part. As a result, the shadow register can be smaller, because inaccuracy in the coverage can be acceptable for larger and very large numbers.

Alternatively, it is possible that the shadow register(s) do not store absolute values, but average values, which, however, may require appropriate calculation logic in the detection element. In particular, the at least one detection element may be set up to provide an average of multiple detection values. This statistical analysis can reduce the effect of outliers in the detection values.

Furthermore, it is possible that the at least one result value, which is determined, for example, in the gate array and/or in the processor unit, can have at least one statistical analysis of several detection values and/or several values derived from the at least one detection value. This leads to a higher accuracy of the analysis.

Furthermore, it is possible that the readout logic may be set up to output the at least one detection value to the processor unit. This can be done, for example, via a bus or via a point-to-point connection. The processor in the processor unit can then perform further analyses of the at least one detection value to generate the result value.

The computer arrangement can have an input and display unit. The input and display unit can be set up to output the at least one detection value and/or the at least a result value to a user. This makes this analysis transparent for the user.

Furthermore, it is possible that the input and display unit enables the input of the model, wherein the at least one detection element is placed in the model, wherein the placement is done manually and/or automatically. The input and display unit can be designed, for example, as a computer on which software for creating the model, e.g., Simulink, is run. This software then also enables the generation and automatic or manual placement of the detection elements.

In addition, it is possible that the input and display unit is set up to display used function parts of the function of the gate array as a function of the at least one result value. For example, a graphical display can be selected that allows a user to see which function parts have already been tested. For this purpose, the input and display unit can be designed, for example, as a computer, which on the one hand uses software for the creation of the model, e.g., simulation software link, and on the other hand has software for visualizing the coverage.

In particular, to visualize coverage, lists of function parts and/or functions can be displayed according to their name and activity, wherein activity can mean how often these function parts or functions have been run through. This activity can be displayed over time as a diagram, in particular displayed as a bar chart. The display can be two- or three-dimensional. A so-called activity map can also be displayed. This means that functions or function parts that have been run are highlighted in terms of color or tints. The more often a function or function part has been run, the more intense the color or tint can be. The model can also be displayed on a web page in a navigable form. After a test, a report can also be created that documents the execution of the functions and function parts. In particular, this includes the frequency in terms of numbers or in the sense of the activity map.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a block diagram of an example of a computer arrangement,

FIG. 2 shows a block diagram of an example of a model,

FIG. 3 shows a block diagram of an example of a detection element,

FIG. 4 shows a block diagram of an example of the detection element,

FIG. 5 shows a block diagram of an example of the model,

FIG. 6 shows a block diagram of an example of the model,

FIG. 7 shows a block diagram of an example of the computer arrangement,

FIG. 8 shows a graphical user interface, and

FIG. 9 shows a flowchart of a method for generating configuration data.

### DETAILED DESCRIPTION

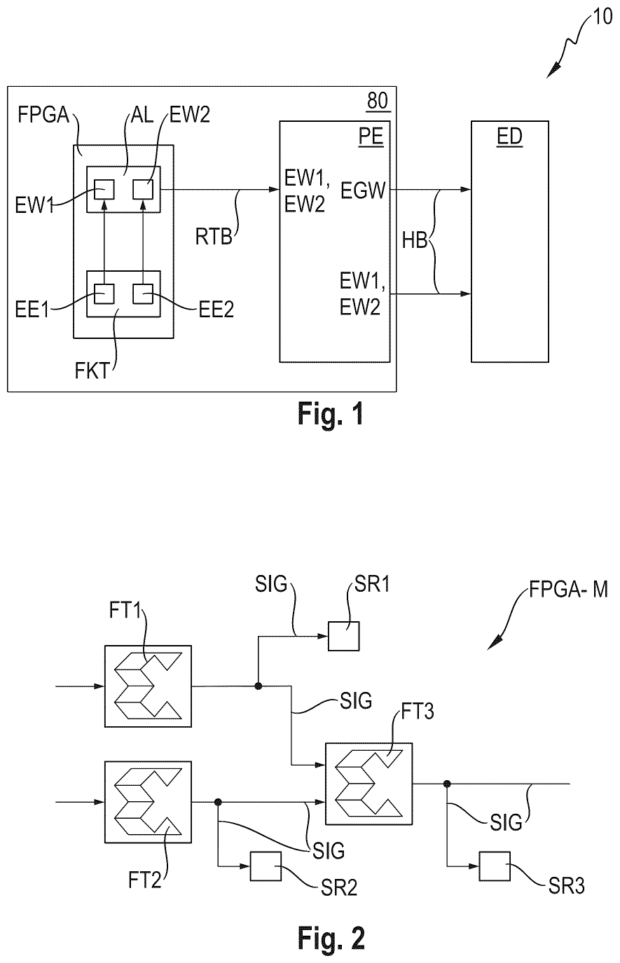

FIG. 1 shows the computer arrangement 10 in a first block diagram. The computer arrangement 10 has three components that are connected to each other. The components are a gate array FPGA, a processor unit PE and an input and display unit ED. The gate array FPGA is connected to the processor unit PE via a real-time bus RTB for data transmission. The gate array FPGA and the processor unit PE can be in particular part of a real-time environment 80 and can, for example, be arranged together on a so-called board. Furthermore, there is a data connection between the processor unit PE and the input and display unit ED via a host bus HB. It is possible that there is also a direct data connection between the gate array FPGA and the input and display unit ED, or that data are only passed through the processor unit PE.

Both the real-time bus RTB and the host bus HB can be designed as data buses that transmit data serially or in parallel. The real-time bus RTB is designed to comply with real-time conditions.

The gate array FPGA has a function FKT with two detection elements, EE1 and EE2. Detection values EW1 and EW2 can be read out from the detection elements EE1 and EE2 using a readout logic AL. The readout logic AL transmits the detection values EW1 and EW2 via the real-time bus RTB to the processor unit PE, which generates a result value EGW from the detection values EW1 and EW2. Statistical evaluations of the detection values EW1, EW2 can be used, for example, for the generation of the result value EW.

The processor unit PE transmits the detection values EW1 and EW2 and/or the result value EGW via the host bus HB to the input and display unit ED. It is possible that only the detection values EW1 and EW2 or only the result value EGW is transmitted. It is also possible that several result values ET are transmitted to the input and display unit ED.

In the input and display unit ED, the result value EGW and the detection values EW1 and EW2 can then be displayed graphically or only with their respective values. The display can be customized according to user input, for example.

FIG. 2 shows a block diagram of a first embodiment of the model FPGA-M with shadow registers SR1, SR2, SR3. The shadow registers SR1, SR2, SR3 each have memory areas or are respective memory areas. In the shadow registers SR1, SR2, SR3, the respective value of the signal SIG can be stored and read out during the execution of the function of the gate array FPGA. The readout of the shadow registers SR1, SR2, SR3 is functionally independent of the execution of the function FKT.

The model FPGA-M has a first function part FT1 and a second function part FT2, each of which outputs a signal SIG. This respective signal SIG is stored in a respective shadow register SR1 and SR2, i.e., each output of a function part FT1, FT2 is provided with a shadow register. These shadow registers SR1, SR2 can then be used to read out the data to check whether the respective function parts FT1, FT2 were also passed through by the signal SIG.

Furthermore, the respective output signals SIG are input to a third function part FT3 as input signals, wherein the output signal SIG of the third function part FT3 is also stored in a shadow register SR3, but is also moved along, e.g., to the next function part FT.

The data in the shadow registers SR1, SR2 and SR3 can then be read out as detection values EW. It is possible that the shadow registers SR1, SR2 and SR3 allow for logarithmic storage. This is a data-saving storage method.

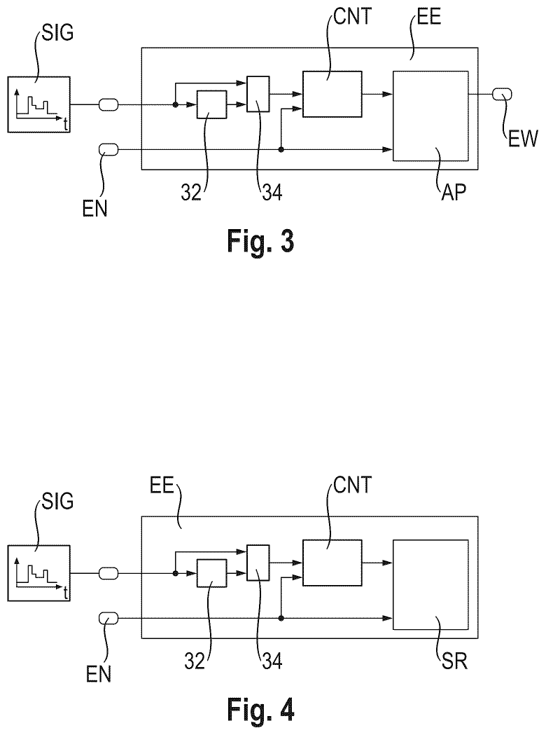

FIG. 3 shows a block diagram of a first embodiment of the detection element EE, which outputs the detection value EW. The detection element EE has several blocks of the gate array FPGA.

The signal SIG is the input signal SIG that is applied to the block 32, which is a delay element, and to the block 34, which is a comparator. Since the output signal of the delay element 32 is also connected to another input of the comparator 34, a comparison of the signal SIG with its delayed self is performed. The output signal of the comparator 34 is transmitted to a counter CNT. The counter CNT is controlled by an enable signal EN at another input. This enable signal EN is also sent to the output port AP, which, as a further input signal, receives the output signal of the counter CNT. This controls that a certain counter value is output as the detection value EW. The enable signal EN activates the counter CNT and the output port AP, respectively. The detection value EW is the output signal of the detection element EE.

FIG. 4 shows a block diagram of a second embodiment of the detection element EE, which contains the signal SIG and the enable signal EN as respective input signals. The detection element EE has several blocks of the gate array FPGA.

Again, as in FIG. 3, the signal SIG is compared with its delayed self by the delay element 32 by the comparator 34. The output signal of the comparator 34 is counted again in the counter CNT. The enable signal EN reactivates the counter CNT. Now, however, the output of the counter CNT is connected to a shadow register SR, to which the enable signal EN is also connected. From the shadow register SR, the detection value EW can then be read out by the readout logic AL, which can correspond, for example, to a configuration interface 70 of the gate array FPGA.

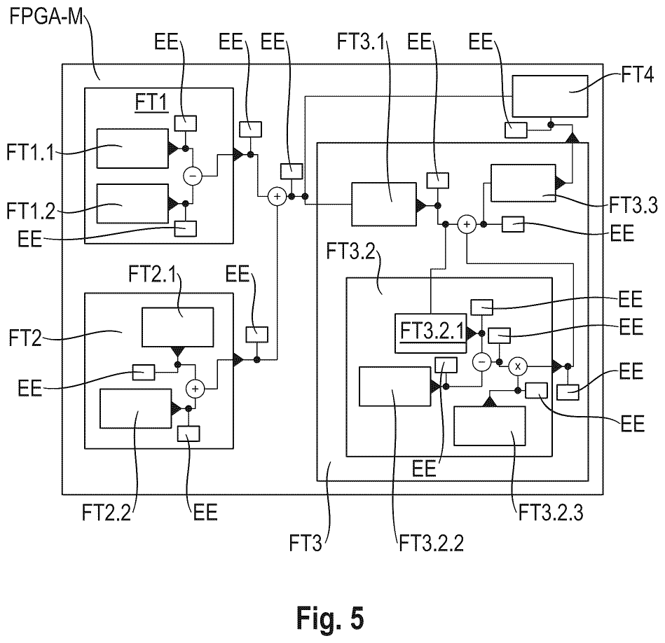

FIG. 5 shows a block diagram of a second embodiment of the model FPGA-M with various detection elements EE placed at the outputs of functions FT1-FT4 and at the outputs of function parts FT1.1-FT3.3. In the present case, four function parts FT1-4 are shown, wherein the function FT4 has no function parts. Together, the function parts FT1-FT4 form the function FKT.

The function FT1 contains the subfunctions FT1.1 and FT1.2, whose output signals are subtracted from each other to match the output signal of the function FT1.

The function FT2 also has two function parts, FT2.1 and FT2.2. The output signals of these function parts FT2.1 and FT2.2 are added to the output signal of the function FT2. The output signals of the functions FT1 and FT2 are also added to an input signal for the functions FT3 and FT4. Every output signal is received by a respective detection element EE and can therefore be monitored.

The function FT3 has three function parts FT3.1, FT3.2 and FT3.3, wherein the function part FT3.2 is divided into three further function parts FT3.2.1, FT3.2.2 and FT3.2.3.

The input signal formed from the output signals of the functions FT1 and FT2 enters the function part FT3.1. The output signal of the function module FT3.1 is on the one hand added to the output signal of the function part FT3.2 and on the other hand it enters the function part FT3.2 as an input signal. There, it is received by the function part FT3.2.1 as an input signal. The output signal of the function part FT3.2.1 is subtracted from the output signal of the function part FT3.2.2 to form an output signal. This output signal is multiplied by an output signal from the function part FT3.2.3. The product thus formed is the output signal of the function part FT3.2.

The sum of the output signals of the function parts FT3.1 and FT3.2 enters the function part FT3.3 as an input signal. An output signal of the function part FT3.3 enters the function part FT4 as a second input signal in addition to the sum of the output signals of the function parts FT1 and FT2.

Each of the output signals or sums, or product, or difference mentioned is monitored and saved by a separately assigned detection element EE. This makes it possible to closely monitor which function parts were run in the test.

Therefore, FIG. 5 shows a large number of detection elements EE, which enable a precise analysis of the coverage of the gate array FPGA during the execution of the function FKT. In particular, the detection elements EE can be used to record how often the respective signals have been changed at these points. The change can be used to detect that this point of the gate array FPGA has been performed.

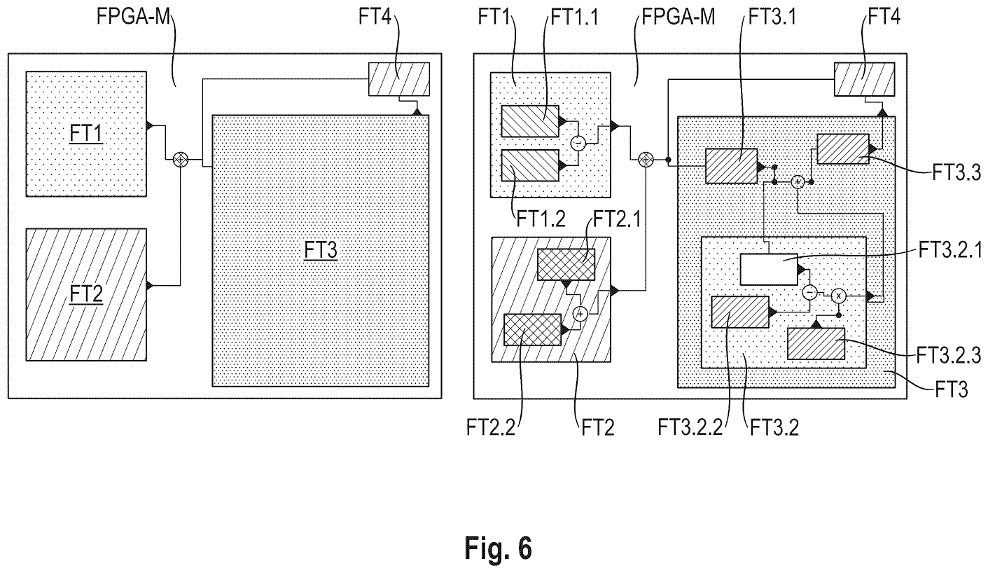

FIG. 6 shows the model FPGA-M in an activity map: In the left image, the functions FT1-FT4 from FIG. 5 on the top level of the function parts FT1-FT4. The picture on the right shows the function parts FT1-FT4 as shown in FIG. 5 on levels within the function parts FT1-FT4. Depending on the shading, the function parts FT1.1-FT3.3 were run through variously often.

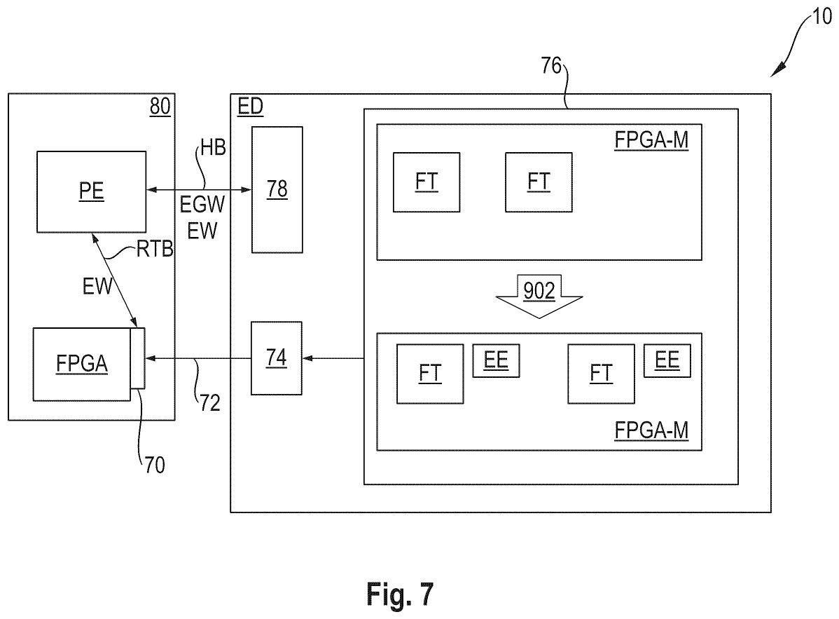

In a block diagram, FIG. 7 shows another embodiment of the computer arrangement 10 with the real-time environment 80, which has the processor unit PE and the gate array FPGA.

The gate array FPGA has a configuration interface 70 which receives configuration data 72 from the input and display unit ED. The configuration data 72 is generated by a generating tool 74 from the model FPGA-M. This configuration data 72 is used by the gate array FPGA for its programming, i.e., the configuration data is used to convert the function FKT, which is defined in the configuration data 72, into electronic hardware in the gate array FPGA.

The programmable gate array FPGA is an integrated circuit of digital technology that is located on a board and into which a logic circuit can be loaded. The processor unit PE can also be optionally installed on the board. Together, the processor unit PE and the gate array FPGA can form the real-time environment 80. By means of the logic circuit, the function FKT can be performed, and signals SIG can be processed. An example of the programmable gate array is a Field Programmable Gate Array. When designing the programmable gate array FPGA, a model FPGA-M can initially be created as a system description on the input and display unit ED. From the model FPGA-M, a description at the logic level, e.g., in the form of a netlist, can then be generated by means of a synthesis, which in particular generates a description of the wiring of the circuit and/or a linking of blocks in text form. The blocks are circuit elements of the gate array FPGA and include computing elements, memory elements, and/or logic circuit elements such as, e.g., AND gates, OR gates, etc. By means of the so-called routing, the so-called design is generated, which additionally generates the arrangement of the circuit elements and the course of the wiring on the board. The programmable gate array FPGA can be programmed by loading the configuration data, called bitstream, onto the board via the configuration interface 70. Programming can also be referred to as configuration. The bitstream is specific to the hardware of the board and is generated from the design. After the input of the bit stream, called programming, the programmable gate array FPGA is set up to perform the function FKT of the logical circuit and to process signals SIG for this.

The configuration interface 70 is also connected via the real-time bus RTB with the processor unit PE for transmitting the detection values EW to the processor input PE. For this purpose, the configuration interface 70 or the gate array FPGA has a bus interface that converts the detection values EW to the bus RTB.

Accordingly, the processor unit PE receives the detection values EW via the bus interface and derives the result values EGW from them. The processor unit PE transmits the result values EGW and the detection values EW via a host bus HB. It is possible that the processor unit PE transmits only the result value(s) EGW or only the detection values EW to the input and display unit ED.

The input and display unit ED receives the detection values EW and/or the result values EGW via a tool for development support 78. This can then be used to display, in particular the graphic display, of the coverage.

The input and display unit ED has a tool for model creation 76. This allows for a user, e.g., to create the model FPGA-M with the function parts FT of the function FKT.

In method step 902 (FIG. 9), the model FPGA-M with the function parts FT is supplemented by the detection elements EE. The model FPGA-M thus completed is then used to generate the configuration data 72, which can be transmitted via the generating tool 74 to the gate array FPGA and there via the configuration interface 70.

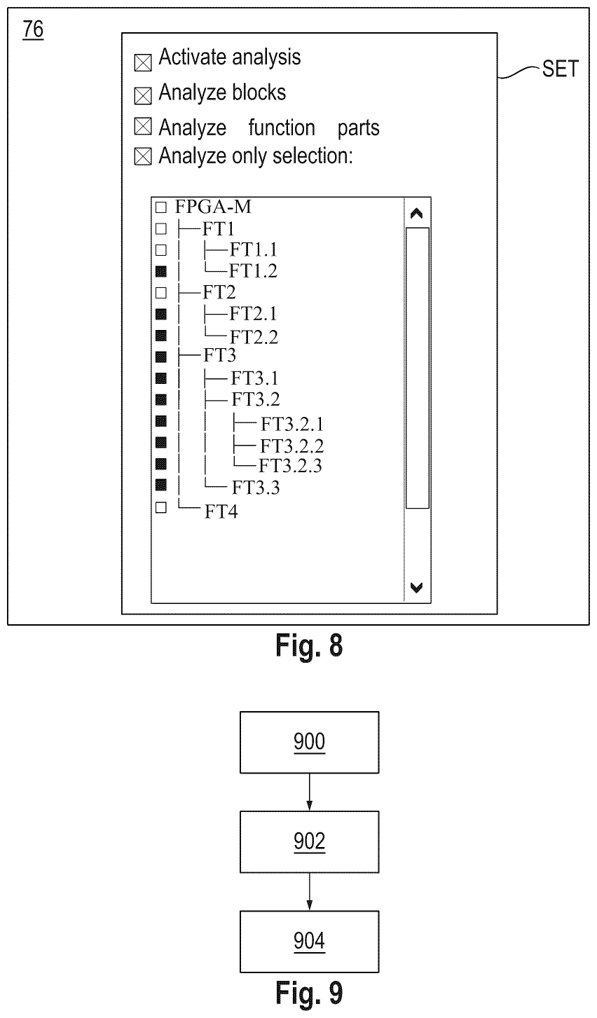

FIG. 8 shows an example of an input field SET of the tool for model creation 76. The analysis of the coverage can be set by the user through the input field SET. By activating certain boxes, it is possible to set whether and which function parts FT of the model FPGA-M are to be detected with regard to coverage. This is done by activating the boxes for, e.g., “activate analysis”, “analyze blocks”, “analyze function parts” and/or “analyze selection only”. Blocks are elementary elements of the gate array. A function part FT can have one or more blocks. In FIG. 8, the function parts FT analogous to FIGS. 5 and 6 are labeled with FT1, FT1.1, FT1.2, FT2. . . . FT3.3, FT4, respectively.

By activating boxes, it is therefore possible to select the function parts FT of the model FPGA-M which are to be detected in terms of coverage. When selecting “analyze selection only”, the test coverage can then be limited to the selected function parts FT by clicking on the corresponding function parts FT.

According to the activation of the boxes, automatic placement of the detection elements EE in the model FPGA-M then takes place in step 902 for detecting the coverage.

FIG. 9 shows a flowchart of a method. In method step 900, the input data for the model FPGA-M is received, e.g., either by user input and/or from stored data and/or from other data transmissions.

In method step 902, an automated placement of at least one detection element EE in the model FPGA-M is carried out. It is also possible to manually place the detection elements EE, or it is possible to manually delete automatically placed detection elements EE. A dialog-controlled placement of the detection elements EE is also possible. The dialog can be carried out, for example, using the input field SET shown in FIG. 8.

In method step 904, the configuration data 72 is then generated from the model FPGA-M as described and transmitted to the configuration interface 70.

When the function parts FT are run on the gate array FPGA, it is determined whether at least one function part FT is being run using a change to the signal SIG. This is provided as a detection value EW via the corresponding detection element EE.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A programmable gate array that is set up to perform a function and to use at least one signal by at least one function part of the function when performing the function, the gate array comprising at least one detection element that is set up to determine, using a change to the signal, whether the at least one function part is being run on the gate array when performing the function, and to provide at least one detection value which is dependent on the determination.

2. The gate array according to claim 1, wherein the gate array is programmable via an input of a model, wherein the model specifies the function performed by the gate array, and wherein the detection element is programmed via the model on the gate array.

3. The gate array according to claim 1, wherein the gate array has a readout logic which is set up to output the at least one detection value provided by the detection element when the function is being performed or after the performance of the function has ended.

4. The gate array according to claim 3, wherein the readout logic is configured to output the at least one detection value via a multiplex unit via a bus or to output it via a slide register chain via a bus.

5. The gate array according to claim 3, wherein the readout logic is configured to output the at least one detection value via a configuration interface via a bus, wherein the configuration interface is set up to receive configuration data for programming the gate array.

6. The gate array according to claim 5, wherein the detection element has at least one shadow register for receiving the at least one detection value, wherein the at least one shadow register has a memory area from which the at least one detection value is read independently of the performed function via the configuration interface.

7. The gate array according to claim 1, wherein the at least one detection element has at least one counter via which a number of changes in the at least one signal are detected, and wherein the at least one detection element is set up to determine, using the number of changes to the at least one signal, how often the at least one function part is run during the performance of the function on the gate array and to provide the at least one detection value dependent on the determination.

8. The gate array according to claim 1, wherein the detection element has the at least one shadow register and is set up to transmit specified bits of the at least one detection value to the at least one shadow register.

9. A computer arrangement comprising:
the gate array according to claim 1; and
a processor that is set up to analyze the at least one detection value to at least one result value.

10. The computer arrangement according to claim 9, wherein the at least one result value has at least one statistical analysis of several detection values and/or several values derived from the at least one detection value.

11. The computer arrangement according to claim 9, further comprising an input and display unit that is set up to output the at least one detection value and/or the at least one result value.

12. The computer arrangement according to claim 11, wherein the input and display unit enables the input of the model, wherein the at least one detection element is placed in the model, wherein the placement is manual and/or automatic, and wherein the input and display unit is set up to display function parts of the function of the gate array used dependent on the at least one result value.

13. The computer arrangement according to claim 9, wherein the computer arrangement is adapted to test a control unit or simulate a control unit.

14. A test device for testing a control unit, comprising the computer arrangement according to claim 9, wherein the gate array is used for testing the control unit via a data exchange with the control unit and/or the control unit is adapted to be simulated via the gate array.

15. A method for generating configuration data for programming a gate array from a model, wherein the model specifies a function to be performed by the gate array, wherein when the function is performed on the gate array, at least one signal is used by at least one function part of the function, the method comprising:
receiving input data to the model;
automatically placing at least one detection element in the model, wherein the at least one detection element is set up to determine when performing the function on the gate array, using a change to the signal, whether the at least one function part is being run, and to provide at least one detection value dependent on the determination; and
generating configuration data for programming the gate array from the model.
